(19) United States
(12) Patent Application Publication
(10) Pub. No.: US 2002/0048969 A1
(43) Pub. Date: Apr. 25, 2002

(54) Method of forming film, method of manufacturing semiconductor device, and film forming apparatus

(75) Inventors: Yoichi Suzuki, Narita-shi (JP); Tsutomu Shimayama, Narita-shi (JP)

Correspondence Address: MOSER, PATTERSON & SHERIDAN, L.L.P., Suite 1500, 3040 Post Oak Blvd., Houston, TX, 77056, US

(73) Assignee: Applied Materials, Inc.

(21) Appl. No.: 10/004,489

(22) Filed: Oct. 23, 2001

(30) Foreign Application Priority Data
Oct. 23, 2000 (JP) P2000-322849

(51) Int. Cl. H01L 21/31

(52) U.S. Cl. 438/778

(57) ABSTRACT

The present invention provides a deposition method and deposition apparatus capable of forming a fluorine-containing silicon inorganic insulating film of stable film properties and a method of manufacturing a semiconductor device. Deposition apparatus 10 comprises parallel plate type electrodes 16, 22 arranged within reaction chamber 12, gas supply sources 20, 32, 34 for feeding process gas containing SiH₄, SiF₄ and oxygen source substance into reaction chamber 12, valves 36, 38, 40, gas mixing chamber 28, and power source 44 that supplies RF power for generating the plasma of the process gas. In this deposition apparatus 10, power source 44 is capable of supplying RF power of at least 1000 Watts to parallel plate type electrodes 16, 22. In this apparatus 10, fluorine-containing silicon oxide film is deposited on wafer 14 by generating the plasma of process gas containing SiH₄, SiF₄ and N₂O.

### BACKGROUND OF THE INVENTION

1. Field of the Invention

The present invention relates to a method of forming a film, a method of manufacturing a semiconductor device and a film forming apparatus.

2. Description of the Related Art

With progress in increasing the density of integrated circuits, wiring gaps have become smaller. These minute wiring gaps are filled with insulator using a high-density plasma (HDP) CVD apparatus.

As wiring gaps are smaller, the capacitance between the wirings increases. One way to reduce the capacitance is to use an insulating film of small relative permittivity, i.e. low-permittivity (low-k) films, for interlayer insulating films. One example for low-permittivity films is a fluorine-containing silicon insulating film.

Conventionally, an HDP apparatus is required to fill the small gaps between wirings, and organosilane-based gas is used as raw material gas to form films for filling gaps.

### SUMMARY OF THE INVENTION

Recently, Damascene structures to form wiring for high-density LSIs has attracted LSI engineers. The Damascene structures do not require the filling of gaps between the wirings with an insulating film, so it is not necessarily essential to employ an expensive HDP apparatus. In this case, one way to form an interlayer insulating film without using the HDP apparatus is, for example, to use a parallel plate type plasma CVD apparatus for forming an FSG film. This CVD apparatus uses TEOS gas as the raw-material gas in forming interlayer silicon oxide films.

However, if these FSG films are formed by the parallel plate type plasma CVD apparatus, their properties thereof gradually change with time and these FSG films lack in stability.

Accordingly, an object of the present invention is to provide a method of forming a fluorine-containing silicon insulating film of stable film properties and an film forming apparatus therefor, and a method of manufacturing a semiconductor device.

In a film forming method according to the present invention, a silicon inorganic insulating film is formed on a substrate in a semiconductor manufacturing apparatus having parallel plate electrodes. This method comprises the step of: (1) depositing, on a substrate, a silicon inorganic insulating film containing fluorine by generating plasma from process gas containing SiH4, SiF4 and an oxygen source substance. This method also comprises the step of (2) introducing process gas containing SiH₄, SiF₄ and oxygen source substance into a chamber.

The present invention relates to a method of manufacturing a semiconductor device having conductive portions with Damascene structure on a substrate. This method of manufacturing a semiconductor device comprises the steps of: (3) depositing, on a substrate, a silicon insulating film containing fluorine by forming plasma of process gas containing SiH₄, SiF₄ and an oxygen source substance, the process gas being introduced into a semiconductor manufacturing apparatus having parallel plate electrodes; and (4) forming conductive portions of Damascene structure on the silicon insulating film.

In the method of manufacturing a semiconductor device according to the present invention, the step of forming conductive portions of Damascene structure comprises the steps of: (4-1) forming depressed portions in the silicon insulating film; and (4-2) forming conductive material in the depressed portions.

As compared with TEOS films, process gas containing SiH₄ and SiF₄ contains principal atomic elements for constituting the resulting silicon inorganic insulating film. Thus, there is little likelihood of entraining carbon and hydrogen into the silicon inorganic insulating film. Since the SiF₄ contains Si—F bonds, fluorine elements are readily entrained into the silicon inorganic insulating film.

Since the Damascene structure does not requite the filling of gaps between conductive portions with silicon inorganic insulating film, this allows the formation of the silicon inorganic insulating film using a semiconductor manufacturing apparatus having parallel plate electrodes.

In the film forming method and semiconductor device manufacturing method according to the present invention, the RF power applied to the parallel plate electrodes can be 1000 Watts or more. The inventors discovered that it was preferable to employ higher RF power in order to obtain a high-quality silicon inorganic insulating film. The larger RF power permits the sufficient decomposition of the process gas containing SiH₄ and SiF₄. The inventors' experiments show that RF power of 1000 Watts or more allows the deposition of the films with excellent quality.

In the film forming method and semiconductor device manufacturing method according to the present invention, the RF power applied to the parallel plate electrodes can be at least 1400 Watts. The RF power of 1400 Watts or more allows the formation of the film with little change of relative permittivity with time. The inventors' experiments show that the high RF power is desirable in making the secular variation of the relative permittivity small.

In the film forming method and semiconductor device manufacturing method according to the present invention, the RF power applied to the parallel plate electrodes can be at least 4 Watts/sccm. The inventors discovered that, in order to obtain a good silicon inorganic insulating film, the RF power per unit flow rate also affects the film properties. The inventors' experiments show that the flow rate of (SiH₄+SiF₄), which is the silicon supplying source, should be at least 4 Watts/sccm.

In the film forming method and semiconductor device manufacturing method according to the present invention, preferably the flow rate ratio of SiF₄ to SiH₄ is larger than 1. The inventors discovered that this flow rate ratio affected the fluorine content of the silicon inorganic insulating film.

In the film forming method and semiconductor device manufacturing method according to the present invention, the RF power applied to the parallel plate electrodes may be modulated with a single frequency. The inventors discovered that the single frequency modulated RF power also allows the satisfactory decomposition of the process gas.

In the film forming method and semiconductor device manufacturing method according to the present invention, the oxygen source substance may include a nitrogen oxide substance, such as N₂O, NO, N₂O₃, N₂O₅, NO₃, N₂O₄ and NO₂, and an oxygen compound, such as CO, CO₂ and H₂O and furthermore may include a substance consisting of elementary oxygen, such as O₂ or O₃.

In the film forming method and semiconductor device manufacturing method according to the present invention, the pressure in the reaction chamber can be 666 Pa or less in the deposition step. The inventors discovered that this pressure influences the film thickness uniformity of the silicon insulating film. the pressure of 666 Pa or less in the reaction chamber can be put to obtain the practical uniformity thereof. Also, the pressure of 522 Pa or less in the reaction chamber results in even better uniformity thereof.

In the film forming method and semiconductor device manufacturing method according to the present invention, the deposition temperature in the deposition step can be 480° C. or less. The inventors discovered that the deposition described above can be carried out even below a temperature at which a eutectic alloy of aluminum and silicon is formed.

In the film forming method and method of manufacturing a semiconductor device according to the present invention, the resulting silicon insulating films exhibit the relative permittivity of 3.4 or less.

In a method of manufacturing a semiconductor device according to the present invention, conductive portions of the Damascene structure is provided on the substrate. This method comprises the steps of: (5) depositing a first silicon insulating film, containing fluorine, on a substrate by generating the plasma of process gas containing SiH₄, SiF₄ and inorganic oxygen source substance introduced into a chamber of a semiconductor manufacturing apparatus having parallel plate electrodes; (6) depositing a second silicon inorganic insulating film on the substrate; and (7) forming conductive portions of the Damascene structure on the first and second silicon inorganic insulating films.

In the method of manufacturing a semiconductor device according to the present invention, in step (6), the second silicon insulating film can be deposited by a generating the plasma of process gas containing SiH₄, SiF₄ and inorganic oxygen source substance to form a fluorine—containing silicon insulating film, and the process gas is introduced into a chamber of a semiconductor manufacturing apparatus having parallel plate electrodes.

In the method of manufacturing a semiconductor device according to the present invention, step (7) comprises the steps of: (7-1) forming a plurality of depressed portions in the first and second silicon inorganic insulating films; and (7-2) forming conductive portions in said depressed portions.

In the method of manufacturing a semiconductor device according to the present invention, prior to step (6), there can be further provided a step of forming, on the substrate, conductive portions containing aluminum. The deposition temperature in step (6) is 480° C. or less. With this temperature, it is hard for a eutectic alloy of silicon and aluminum to be formed.

In the method of manufacturing a semiconductor device according to the present invention, step (7) is performed after step (6). The method further comprises a step of: forming a silicon insulating film containing silicon and nitrogen after step (6) but prior to step (7). The silicon insulating film is provided between the first and second inorganic silicon insulating films and the depressed portions is formed in the first and second insulating films. Thus, this configuration allows the control of the depth of the depressed portions.

A film forming apparatus according to the present invention comprises: (8) parallel plate electrodes provided within a chamber; (9) means for introducing process gas containing SiH₄, SiF₄ and oxygen source substance into the chamber; and (10) a power source supplying RF power for generating the plasma of the process gas. In this deposition apparatus, the power source is capable of supplying RF power of 1000 Watts or more to the parallel plate electrodes.

This configuration provides a film forming apparatus capable of carrying out in the film forming method and the semiconductor device manufacturing method according to the present invention.

In the film forming apparatus according to the present invention, the separation distance between the parallel plate electrodes is not less than 0.5 cm and no more than 1.75 cm. The inventors discovered that film properties are improved if this separation is made small.

In the film forming apparatus according to the present invention, the power source can modulate the RF power, applied to the parallel plate electrodes, with a single frequency.

A semiconductor integrated circuit device according to the present invention comprises: (11) a plurality of semiconductor active elements, (12) a silicon insulating film, and (13) conductive portions. The semiconductor active elements are provided on the substrate. The silicon insulating film contains fluorine and is provided on the semiconductor active elements. The conductive portions are provided within the silicon inorganic insulating film so as to establish connection between the semiconductor active elements. The conductive portions have Damascene structure and include wiring conductors. The silicon inorganic insulating film is formed using process gas containing SiH₄, SiF₄ and oxygen source substance in a semiconductor manufacturing apparatus having parallel plate electrodes.

The aforesaid objects and other objects, features and advantages will easily be understood from the following detailed description of preferred embodiments of the present invention with reference to accompanying drawings.

### BRIEF DESCRIPTION OF THE DRAWINGS

FIG. 1 is a diagram of a film forming apparatus; FIGS. 2A to 2D are views illustrating film forming steps;

FIG. 3 is a view illustrating deposition conditions; FIG. 4 is a view illustrating the properties of an FSG film;

FIG. 5 is a view illustrating the properties of an FSG film;

FIG. 6 is a view illustrating the relationship between SiF4 flow rate and Si—F peak;

FIG. 7 is a view illustrating the relationship between Si—F peak and relative permittivity;

FIG. 8 is a view illustrating the relationship between relative permittivity and refractive index;

FIG. 9 is a view illustrating the water absorption property of the film; and

FIGS. 10 to 14 are cross-sectional views illustrating process steps for the third embodiment.

### DESCRIPTION OF THE PREFERRED EMBODIMENTS

Embodiments of the present invention are described with reference to the drawings. Identical and similar portions are designated as the same reference symbols, if possible, to avoid redundant description.

First Embodiment

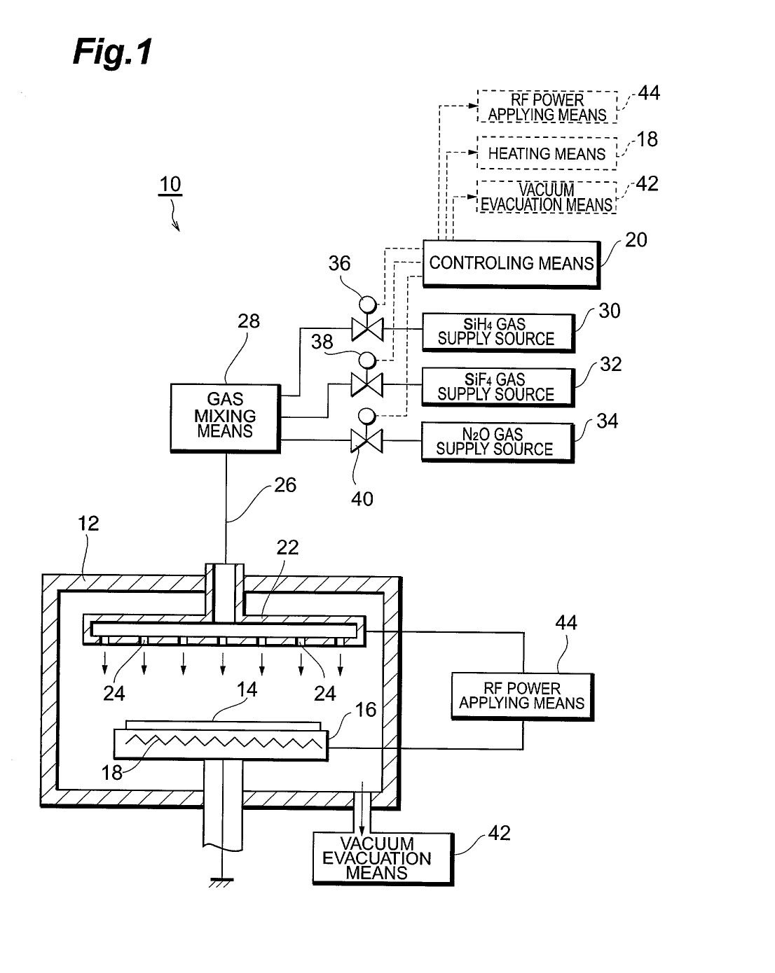

FIG. 1 illustrates a chemical vapor deposition (CVD) apparatus capable of performing a method of forming a silicon insulating film according to the embodiment.

CVD device 10 comprises processing chamber 12. The pressure of processing chamber 12 can be reduced to a desired degree of vacuum. Within processing chamber 12, there is provided substrate supporting means, for example, pedestal 16, for supporting substrate 14, such as a silicon wafer, which is to be treated. Pedestal 16 comprises heating means 18, including a ceramics heater, provided so as to heat silicon wafer 14. Heating means 18 is controlled by control means 20 comprising a memory and a microcomputer entirely controlling the system. Heating means 18 can be controlled such that the temperature of pedestal 16, i.e. the stage temperature, is kept around a deposition temperature suitable for film deposition. In this way, the temperature of substrate 14 is controlled by heating means 18.

Within processing chamber 12, gas distribution plate 22 is arranged so as to face pedestal 16. Gas distribution plate 22 is arranged parallel with pedestal 16 so as to uniformly supply gas to substrate 14. Gas distribution plate 22 is a hollow plate with a plurality of gas distribution holes 24. The gas distribution holes 24 are arranged in one face, facing pedestal 16, of gas distribution plate 22. Process gas is supplied through a distribution pipe 26 from a gas mixing chamber 28, arranged outside the processing chamber, to the interior of gas distribution plate 22. Gas mixing chamber 28 uniformly mixes a carrier gas and a raw-material gas necessary for film deposition beforehand. This embodiment shows process gas supplying sources 30, 32 and 24 for forming a silicon insulating film, in particular a silicon oxide film containing fluorine (for example, a film called an FSG film) SiH₄ gas supplying source 30, SiF₄ gas supplying source 32 and oxygen source substance (for example, N₂O) supplying source 34 are respectively connected with gas mixing chamber 28 by means of flow rate regulating valves 36, 38 and 40. The oxygen source substance provides oxygen elements for forming Si—O bonds in the silicon insulating film. The process gas supply source may further comprise a supply source for inert gas, such as Ar, for plasma generation. Gas flow rate adjustment valves 36, 38 and 40 can be controlled by control means 20, so the flow rate of each gas can be adjusted so as to be mutually associated with each other. Gas distribution plate 22 is made of electrically conductive material, such as, aluminum.

Vacuum evacuation means 42, such as a vacuum pump, is connected with processing chamber 12. When the vacuum pump is operated, the interior pressure of processing chamber 12 can be reduced to a desired degree of vacuum. Vacuum evacuation means 42 is controlled by control means 20 as well.

CVD device 10 comprises parallel plate type electrodes. This paired electrodes can be composed of pedestal 16 and gas distribution plate 22. The separation distance of the paired electrodes falls within a range of preferably at least 0.5 cm and not more than 1.75 m. The electrodes are connected with RF power generating means 44 including an RF power generator. The RF power generator applies RF power of at least 1000 Watts (at least preferably 1400 Watts) and not more than 2000 Watts to the pair of electrodes. Control means 20 can control the turn-on/off and magnitude of this applied power. The frequency of RF power generator 44 is chosen to be 13.56 MHz, but the frequency is not limited thereto. Frequencies in a range of at least 3 MHz and not more than 30 MHz can be employed as well.

Fluorine-containing silicon inorganic insulating film can be formed using a film forming apparatus as described above. This fluorine-containing silicon inorganic insulating film is a dielectric film containing at least fluorine in addition to silicon and oxygen.

Second Embodiment

With referring to FIG. 1 and FIGS. 2A to 2D, the process steps of forming a silicon oxide film on a substrate using CVD apparatus 10 will be described below.

Interlayer insulating film 3 and metallic wiring film 4 are deposited on the main surface of substrate 2, such as a silicon wafer. Intermediate product 14 to be processed comprises substrate 2, interlayer insulating film 3 and metallic wiring film 4. The stage temperature is adjusted to be a temperature in the range of at least 300° C. and not more than 480° C. by heating means 18. As shown in FIG. 2A, intermediate product 14 is arranged on pedestal 16 of CVD device 10.

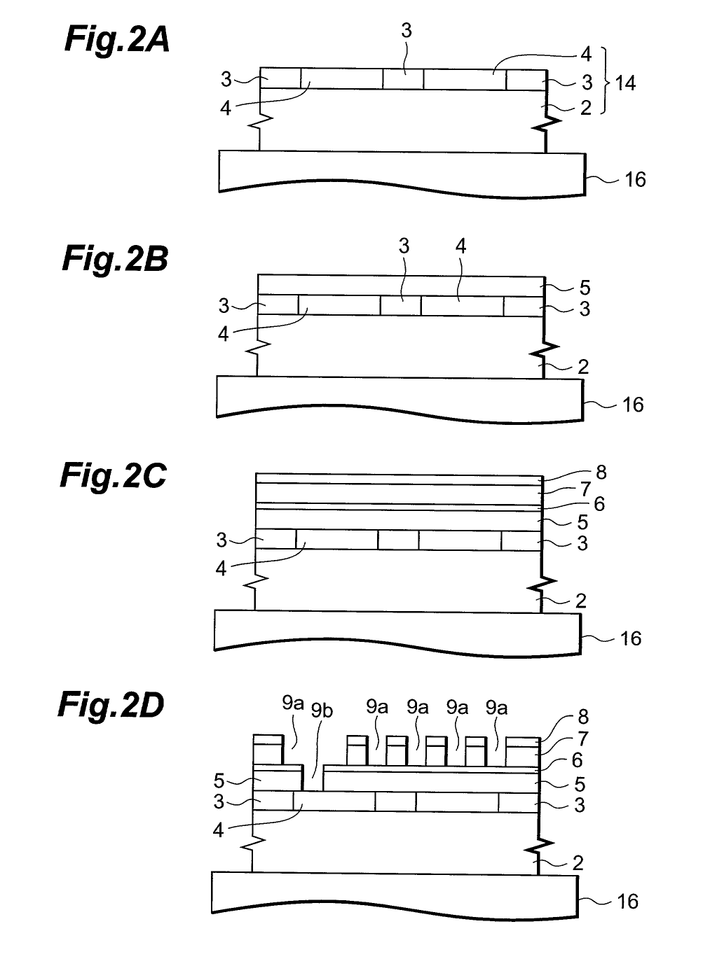

First, fluorine-containing silicon oxide film (FSG film) 5 is formed on intermediate product 14. The deposition conditions are shown in the column “Test Conditions” in FIG. 3. Referring to FIG. 3, the RE power of 13.56 MHz is 1500 Watts; the separation distance of the parallel plate electrode is 1 cm; the internal pressure of the chamber is at 493 Pa (3.7 torr); the N₂O gas flow rate is 1500 sccm; the SiH₄ gas flow rate is 115 sccm; the SiF₄ gas flow rate is 130 sccm. “Sccm” is the abbreviation of Standard Cubic Centimeter per Minute.

Nitrogen-containing silicon insulating film 6 is then formed on FSG film 5 in CVD apparatus 10. The nitrogen-containing silicon insulating film exhibits low etching rate to the etching gas used to etch the FSG film, and acts as an etching stop film.

Next, FSG film 7 is formed on silicon insulating film 6 in CVD apparatus 10. The same deposition conditions can be used as those indicated in column “Test Conditions” in FIG. 3, which is limited thereto.

Nitrogen-containing silicon insulating film 8 is formed on FSG film 7 in CVD apparatus 10. Nitrogen-containing silicon insulating film 8 works as an anti-reflection film in the etching process of the FSG film. Each of nitrogen-containing silicon insulating films 6 and 8 includes a silicon nitride film, such as Si₃N₄ film, SiN film and SiON film.

Thereafter, depressed portions are formed in FSG film 5, nitrogen-containing silicon insulating film 6, FSG film 7, and nitrogen-containing silicon insulating film 8. Then, silicon insulating film 8 is patterned to transfer a wiring pattern thereto by a photolithographic method and dry etching method. Depressed portions 9a are formed in FSG film 7 by dry etching with a mask of the patterned silicon insulating film 8. This etching is carried out to etching stop film 6. An etching rate for the etching stop layer 6 becomes low, so that the etching is not carried out substantially. Next, nitrogen-containing silicon insulating film 6 is patterned by photolithography and dry etching to transfer the via-hole positions. Thereafter, depressed portions 9b are formed in FSG film 5 by dry etching using the patterned silicon insulating film 6 as a mask. The etching proceeds to the underlying wiring layer 4.

Then, damascene conductors are formed by filling depressed portions 9a, 9b with metallic material so as to flatten them. The sequence of manufacturing steps described above may be repeated until the number of wiring multi-layers are obtained as required.

It should be noted that the inorganic silane-based gas is employed in the above deposition step for forming the silicon oxide film in a CVD chamber, so that a nitrogen-containing silicon insulating film can easily be formed using inorganic silane-based gas in the same CVD chamber after the silicon oxide film is formed.

Apart from the Test Conditions shown in FIG. 3, the inventors conducted experiments while changing conditions within the ranges of conditions shown in FIG. 3.

FIG. 4 shows the relationship between the strength of Si—F peak and the variation of refractive index while the RF power of a parameter is varied. FIG. 4 also shows the properties of FSG films formed in the RF power ranging from 1400 to 2000 Watts. The horizontal axis shows Si—F peaks of FT-IR spectrum in a percentage ratio of SiF/(SiF±SiO) and shows the relative permittivity. The vertical axis shows the difference IN_{after}−N_{before}I of refractive index measured before and after the specimen has been left for three days in a clean room. Symblo “n_{before}” is the refractive index before the three-day left, and symbol “n_{after}” is the refractive index after three-day left. The symbol “♦” represents the data of RF power of 2000 Watts, the symbol “●” represents the data of RF power of 1800 Watts, the symbol “▴” represents the data of RF power of 1600 Watts and the symbol “▪” represents the data of RF power 1400 Watts. With RF power of 2000 Watts, the change of the index is less than 0.007; with RF power of 1800 Watts, the change of the index is less than 0.0085; with RF power of 1600 Watts, the change of the index is no more than 0.010; with RF power of 1400 Watts, the change of the index is less than 0.012. According to FIG. 4, increasing the RF power allows the formation of films having smaller change in refractive index, i.e. the formation of films having more stable property.

The inventors discovered that the RF power not less than 1000 Watts allowed the formation of silicon oxide films with little secular change in their film property.

Furthermore, the inventors discovered that not only the RF power but also the ratio of the applied RF power to the total flow rate of SiH₄ gas and SiF₄ gas is important. This value is at least 4 Watts/sccm.

Furthermore, in the experiments described above, excellent film properties were obtained with the RF power of at least 1000 Watts per wafer. The power density is 3.18 Watts/cm² where the power is 1000 Watts. The power density is 4.46 Watts/cm² where the power is 1400 Watts; the power density is 5.10 Watts/cm2 where the power is 1600 Watts; the power density is 5.73 Watts/cm2 where the power is 1800 Watts; the power density is 6.37 W/cm2 where the power is 2000 Watts.

In addition, the inventors discovered that it was desirable that the flow rate of SiF₄ is larger than that of SiH₄ in depositing film in high RF power. This condition is preferable to control the content of fluorine in the deposited films.

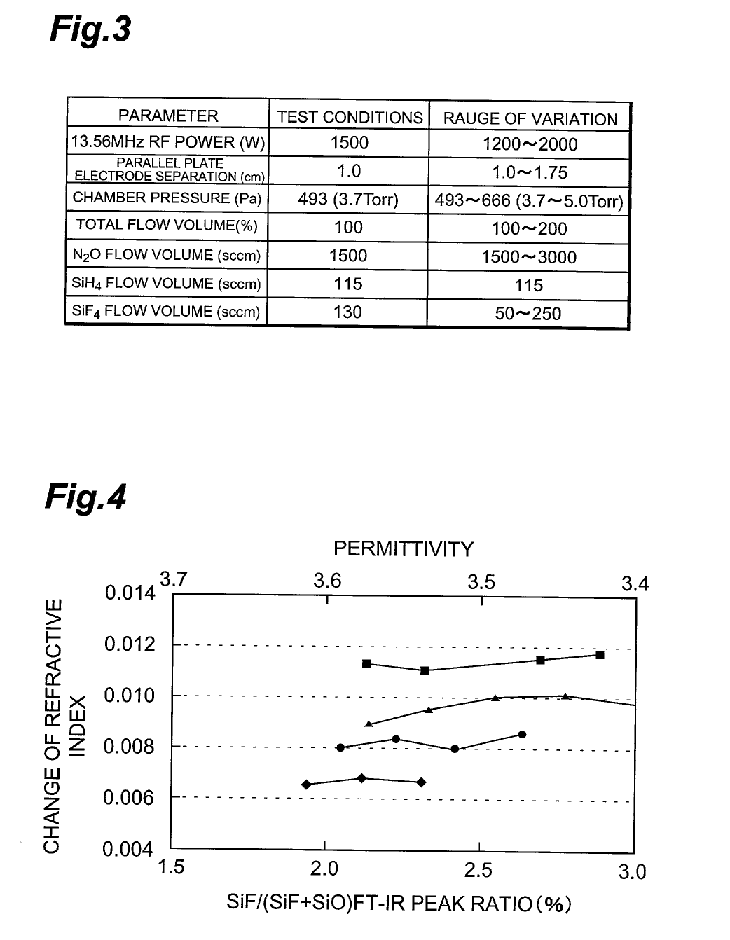

FIG. 5 shows the relationship between the intensity of Si—F peak and the variation of refractive index while varying any one of the film forming parameters listed in the Test Conditions in FIG. 3. The horizontal axis shows the percentage ratio of SiF/(SiF+SiO) at the Si—F peak in the FT-IR spectrum. The vertical axis shows the difference In_{after}−n_{before}I of refractive index measured before and after the test samples are left standing for three days in a clean room.

FIG. 5 shows curves CI to CS. In curves CI to CS, the ratio of the SiF₄ gas flow rate to the SiH₄ gas flow rate was varied in order to change the fluorine concentration in the film. For curve CI, the same Test Conditions were used except for conditions of SiH₄ gas flow rate and SiF₄ gas flow rate. For curve C2, the same Test Conditions were used except for the alteration of the N₂O gas flow rate from the original value to 3000 sccm. For curve C3, the same Test Conditions were used except for the alteration of the pressure in the chamber from the original value to 666 Pa (5 torrs). For curve C4, the same Test Conditions were used except for the alteration of the separation distance of the parallel plate electrodes of the CVD device from 10 to 1.7S cm. For curve CS, the same Test Conditions were used except for the doubling of respective flow rates of SiH₄ gas, SiF₄ gas and N₂O gas.

FIG. 5 shows that the film quality is improved if the flow rate of N₂O gas, acting as oxidizing agent, is greater than that in the Test Conditions and that the film quality is also improved if the pressure within the chamber is lower than that in the Test Conditions.

In particular, lowering the pressure in the chamber is effective for improving the uniformity of the film thickness on the substrate. FIG. 5 shows that decreasing the distance between the electrodes of CVD device 10 is advantageous to improving film properties and decreasing the total flow rate of the process gas is advantageous to improving film properties.

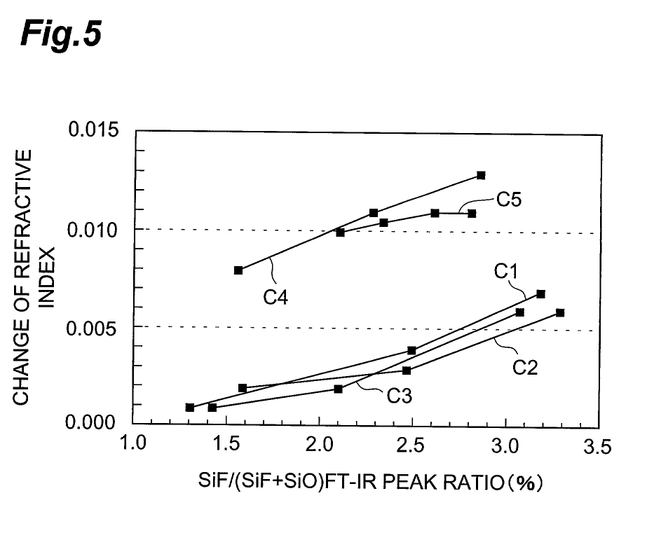

FIG. 6 shows the relationship between SiF₄ gas flow rate and the variation of refractive index. Symbols “E” indicate the deposition data at a deposition temperature of 400° C. and symbols “▪” indicate the deposition data at a deposition temperature of 480° C. The horizontal axis indicates the percentage of (SiF₄ flow rate)/(SiH₄ flow rate±SiF₄ flow rate) and the vertical axis indicates the Si—F peak in the FT-IR spectrum in terms of SiF/(SiF+SiO) percentage. The percentage on the vertical axis increases to about 2% at a flow rate ratio of about 50%.

FIG. 6 shows that the intensity of the Si—F peak becomes larger as the ratio of SiF₄ flow rate becomes larger. FIG. 6 also shows little dependence on deposition temperature, so these deposition conditions in this embodiment provide a wide process window with regard to deposition temperature change.

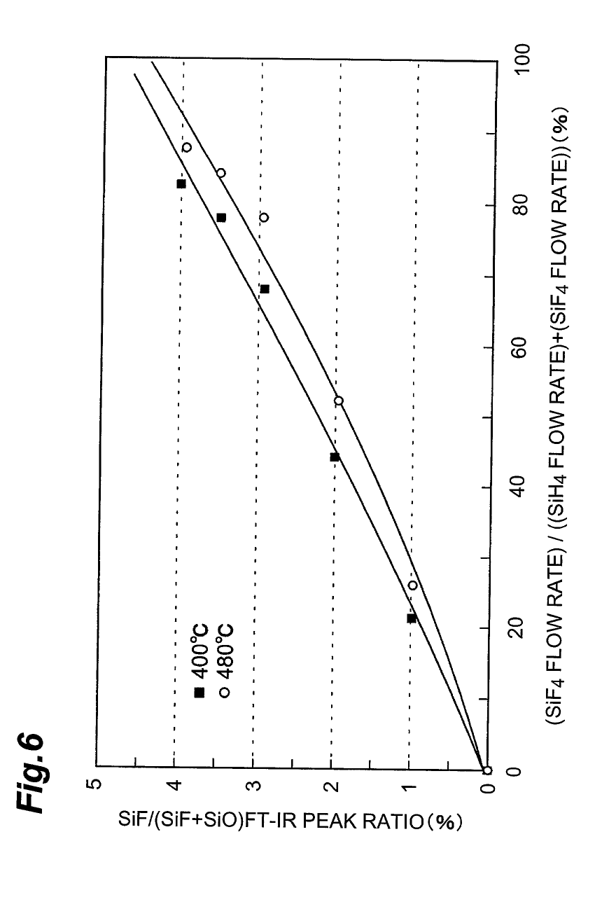

FIG. 7 shows the relationship between Si—F peak intensity and relative permittivity of the oxide film. The horizontal axis indicates the Si—F peak in the FT-IR spectrum in terms of SiF/(SiF+SiO) percentage. The vertical axis indicates the relative permittivity of the silicon oxide film.

FIG. 7 shows that the relative permittivity of the silicon oxide film decreases as the Si—F peak becomes larger. This film contains fluorine atoms therein, which are capable of effectively reducing the permittivity of film. Regarding the deposition temperature, the permittivity of films deposited at 400 C. tends to be lower than that of films deposited at 480 C.

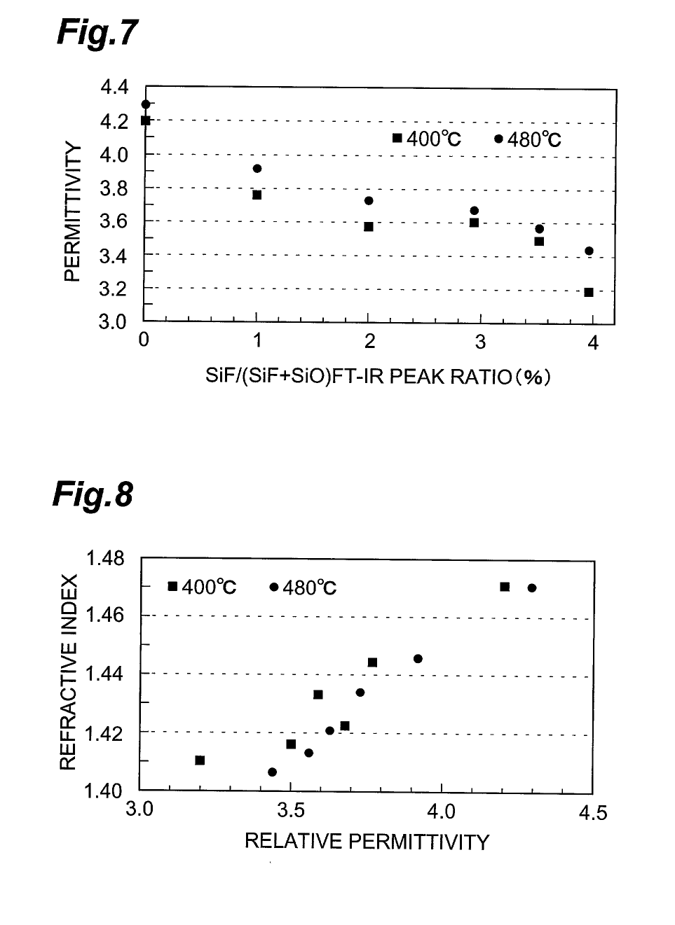

FIG. 8 shows the relationship between the relative permittivity and refractive index of the silicon oxide films. The horizontal axis shows the relative permittivity of silicon oxide films. The vertical axis shows the refractive index of silicon oxide films. FIG. 8 shows that the refractive index of the silicon oxide films decreases as the relative permittivity of the silicon oxide films decrease.

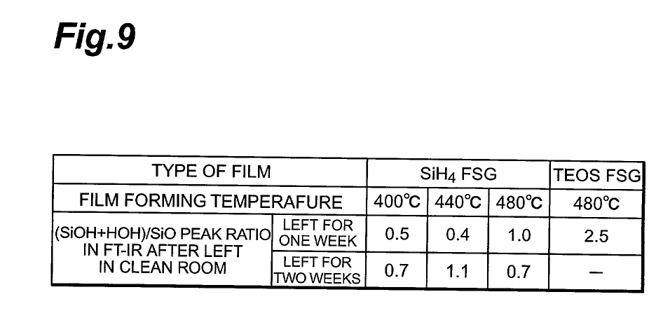

FIG. 9 shows the characteristics of the water absorption rates for a TEOS/FSG film and a silane FSG film according to an embodiment of the present invention. The water absorption rate is expressed as a percentage of the (SiOH+HOH)/SiO peak in the FT-IR spectrum. FIG. 9 also shows the difference between the water absorption rates measured prior to and subsequent to leaving the silane FSG films for one week and two weeks in a clean room; These silane FSG films were deposited at the respective deposition temperatures of 400 C., 440 C. and 480 C.

According to FIG. 9, whereas the variation of the water absorption rate for the silane FSG films is about 1% at most, the variation of the water absorption rate for the TEOS/FSG film is about 2.5%. The characteristics of the silane FSG film is immensely superior to that of the TEOS/FSG film.

By making an overall evaluation of the experiments, the inventors determined suitable deposition conditions as:

RF power: 1500 Watts

Film forming temperature: 400° C.

Inter-electrode spacing: 0.1 cm

Internal chamber pressure: 533 Pa (4.0 torr)

N₂O gas flow rate: 2500 sccm

SiH₄ gas flow rate: 60 sccm

SiF₄ gas flow rate: 200 sccm.

The film properties achieved under these conditions were:

Deposition rate: 420 (nm/minutes)

Uniformity of film thickness on a substrate: 3.5%

Film stress: −0.7×1010 N/m2(−0.7×109 dyne/cm2)

Refraction coefficient: 1.42

Relative permittivity (as deposition): 3.4

The inventors believe that the silane FSG film exhiflits the excellent film properties because Si, F and 0 atoms constituting the silane FSG film form a dense network, but the conventional TEOS/FSG film contains relatively more C and H atoms in addition to the atoms Si, F and 0 constituting the silicon oxide films, so the network becomes coarse. In film deposition according to this embodiment, fine film of density 2.1×103 kg/ms (2.1 g/cm³) is obtained with a 3.5% fluorine concentration. In contrast, the density of the TEOS/FSG film was 1.8×103 kg/in³ (1.8 g/cm³) for a fluorine concentration of 3.5%.

The inventors made the following deductions: This embodiment employed the supply source of Si, F and O, inorganic silane based gas to form a film, which does not contain relatively large amounts of hydrogen (H) atoms and carbon (C) atoms as does TEOS. Therefore, impurities are unlikely to be included in the film. Also, the SiF₄ and SiH₄ are thoroughly decomposed by supplying sufficient RF power. This film contains little SiF₂ fragments and the Si—H bonds of SiH₄ are fully decomposed, so that this film becomes dense and the water absorption rate is reduced. (Third embodiment)

In the subsequent description, another aspect of the present invention, which relates to a semiconductor integrated circuit including semiconductor active devices, such as MOS devices, will be described, but the present invention is not restricted thereto.

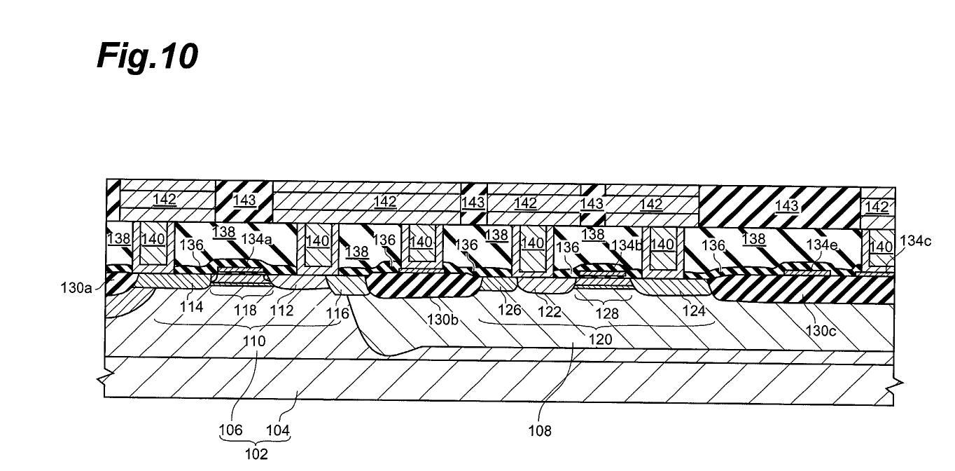

FIGS. 10 to 14 are cross-sectional views illustrating manufacturing process steps in the third embodiment.

Referring to FIG. 10, substrate 102 comprises a P type epitaxial layer 106 on a P type heavily doped wafer 104. An N channel MOS type device 110 and P channel MOS type device 120 are provided on substrate 102.

N channel device 110 is formed in the surface layer of P type epitaxial layer 106. N well 108 is formed so as to include a region for forming P channel type device 120. Device isolation regions 103a, 103b and 103c are provided so as to respectively isolate N channel device 110 and P channel device 120 from each other. Regions enclosed by these element isolation regions 130a to 130c is called device forming region.

Next, gate insulating film 132 is formed in the device forming regions. Gate electrodes 134a to 134e are formed on gate insulating film 132. Impurity is introduced into regions 118, 128 just below gate electrodes 134a, 130b in order to determine the threshold voltages of the MOS devices. N type source diffusion region 112 and N type drain diffusion region 114 are formed so as to be self-aligned with gate electrode 134a. Also, P type source diffusion region 122 and P type drain diffusion region 124 are formed so as to be self-aligned with gate electrode 134b. P type diffusion region 116 is arraTiged adjacent to N type source diffusion region 112 and P type diffusion region 126 is arranged adjacent to P type source diffusion region 122.

First silicon nitride film 136 containing an Si₃N₄ film is formed on substrate 2. First silicon nitride film 136 acts as an etching stop film for forming self-aligned contacts.

First silicon oxide film 138 is formed on first silicon nitride film 136. First silicon oxide film 138 may be an FSG film. For example, the FSG film has a thickness of at least 500 nm and no more than 1000 nm and is formed in the CVD method. After this formation, contact holes are formed. The contact holes are provided through the first silicon oxide film 138 and first silicon nitride film 136 so as to reach the surface of substrate 102 and the gate electrodes. Within these contact holes, filling plugs 140 made of a tungsten (W) plug are formed. Prior to filling with tungsten, a TiW film is formed on the side surfaces and the bottom surface of the contact holes. This TiW film may be formed by sputtering and the tungsten plugs may be formed by a CVD method. After forming the filling plugs 140, silicon oxide film 138 and filling plugs 140 are planarized in CPM method.

First wiring layer 142 is formed on the planarized silicon oxide film 138 and filling plugs 140. First wiring layer 142 is composed of three films, for example, a TiN film, W film and TiN film formed in sputtering method, CVD method and sputtering method, respectively. Also, first wiring layer 142 is provided to pattern these films with wiring. For example, first wiring layer 142 has a thickness of at least 500 nm and not more than 1000 nm.

Second silicon oxide film 143 is deposited on first wiring layer 142 and silicon oxide film 138. Second silicon oxide film 143 is formed in a film deposition apparatus capable of sufficiently filling the gaps of first wiring layer 142. After forming second silicon oxide film 143, first wiring layer 142 and second silicon oxide film 143 are planarized.

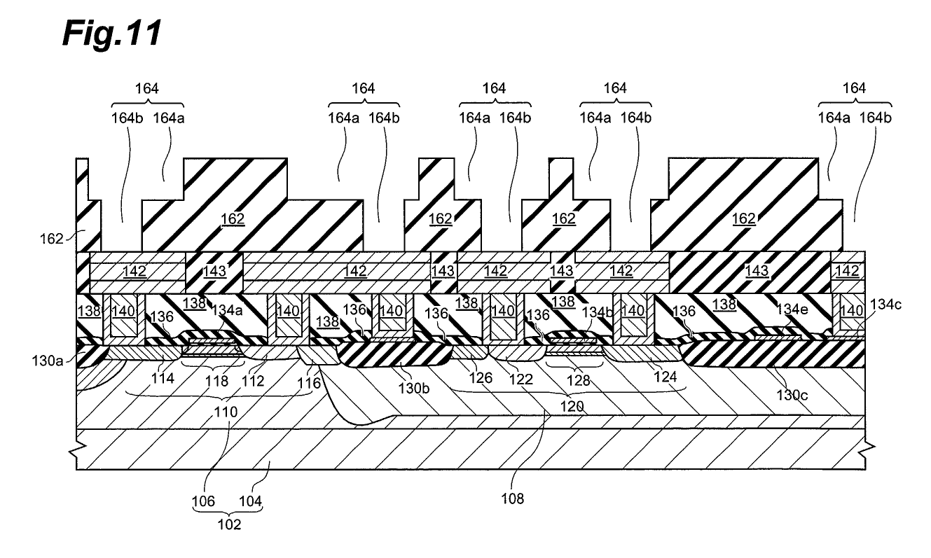

With reference to FIG. 11, the formation of upper wiring layers will be described. Third silicon oxide film 162, filling plugs 166b and second wiring layer 166a are formed on second silicon oxide film 143 and first wiring layer 142. Third silicon oxide film 162 is an FSG film, having a thickness of at least 500 nm and not more than 2000 nm formed in CVD method, for example.

In this embodiment, wiring conductors and via plugs are formed together in a dual Damascene method. However, it is possible to employ a single Damascene method for forming these wiring and via plugs.

First of all, depressed portions 164a are formed in third silicon oxide film 162 in a photolithographic method and a dry etching method. Second wiring layer 166a is formed in these depressed portions 164a. Depressed portions 164a have a shape reflecting the depth and width of wiring layer 166a to be formed. Next, depressed portions 164b are formed in a photolithographic method and dry etching method. Depressed portions 164b are provided for via plugs 166b that electrically connects first wiring layer 142 with second wiring layer 166a. Thus, depressed portions 164b extends from the bottom of depressed portions 164a and has its depth determined so as to reach the upper surface of first wiring layer 142. It should be noted that second silicon oxide film 162 may be separated into two layers by a silicon nitride film provided at the boundary of depressed portions 164a and depressed portions 164b. This configuration can enhance the controllability of the depth of these depressed portions.

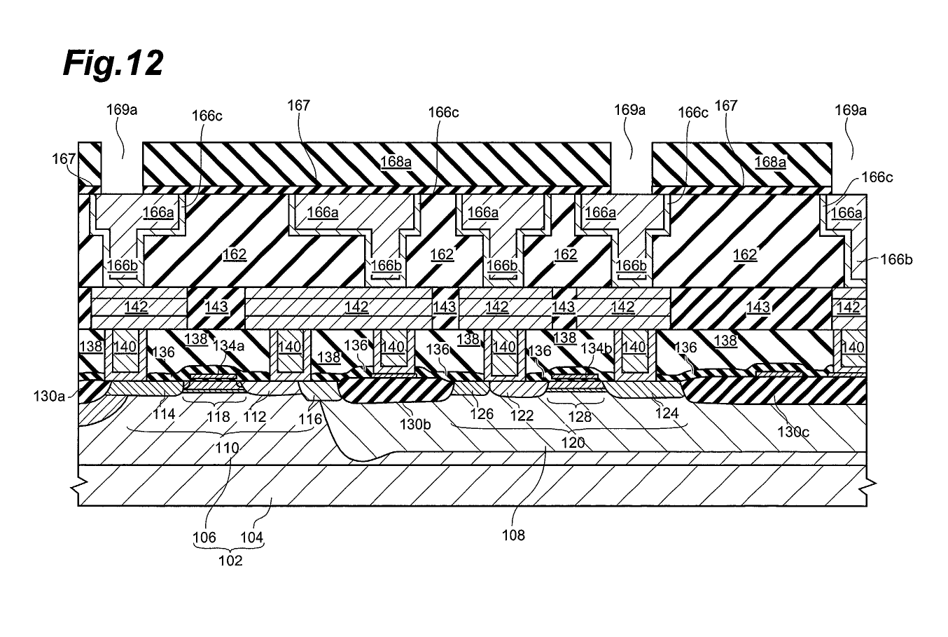

Referring to FIG. 12, depressed portions 164a and 164b are filled with conductive material in the same processing step. This filling is performed in the following. First of all, first conductive layer 166c acting as a diffusion barrier layer or adhesive layer, such as a TaN film or TaSiN film, is formed over the entire surface of the wafer. First conductive layer 166c is deposited by, for example, sputtering in a thickness of the range of at least 30 nm and not more than 100 nm to form first conductive layer 166c on the bottom and side of depressed portions 164a, 164b. Then, second conductive layers 166a and 166b are formed by filling depressed portions 164a, 164b with conducting material, for example, copper (Cu). After forming a seed layer of thickness of the range of at least 50 nm and not more than 100 nm using for example a sputtering method, the Cu conductor is formed in a thickness of the range of at least 1 μm and not more than 5 pm in an electrolytic plating method. Preferably, the thickness of the conductor should be determined not only to fill depressed portions 166a and 166b but also to allow the planarization thereof in the subsequent step. As understood from the above description, second wiring layer 166a and connecting via plugs 166b constitute first conductive member 166 formed in the same process step.

Third silicon oxide film 162 and first conductive member 166 are planarized as shown in FIG. 12 in a planarization method, such as CMP method. Thin silicon nitride film 167 can be formed on the planarized third silicon oxide film 62 and first conductive member 166.

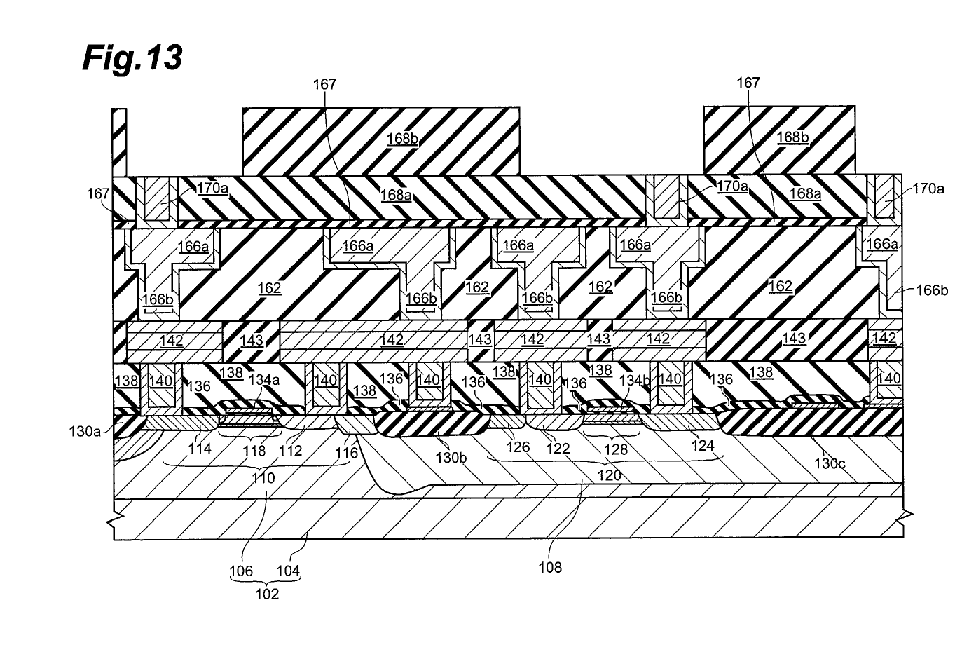

After this step, second conductive member 170a is formed by a single Damascene method in a fourth silicon oxide film 168a. First of all, fourth silicon oxide film 168a is formed on silicon nitride film 167. Fourth silicon oxide film 168a can be an FSG film like fourth silicon oxide film 162 as described above. Next, depressed portions 169a are formed in fourth silicon oxide film 168a, and depressed portions 169a will be filled with second conductive member 170a in later steps. Depressed portions 169a are formed in a photolithography and dry etching method by etching silicon oxide film 168a and silicon nitride film 167 to conductor 166a. Second conductive member 170a is formed by the same manufacturing process as first conductive member 166 in depressed portions 169a, as shown in FIG. 13. Fourth silicon oxide film 168a and second conductive member 170a are planarized by CMP.

Referring to FIG. 13, third conductive member 170b is formed within fifth E silicon oxide film 168b by a single Damascene method. Third conductive member 170b is formed by filling depressed portions 169b with conductive material. As described above, this filling is achieved in the same manufacturing process as second conductive member 170a, so a detailed description thereof is omitted, but this in not limited thereto. So another manufacturing process can be used for forming it.

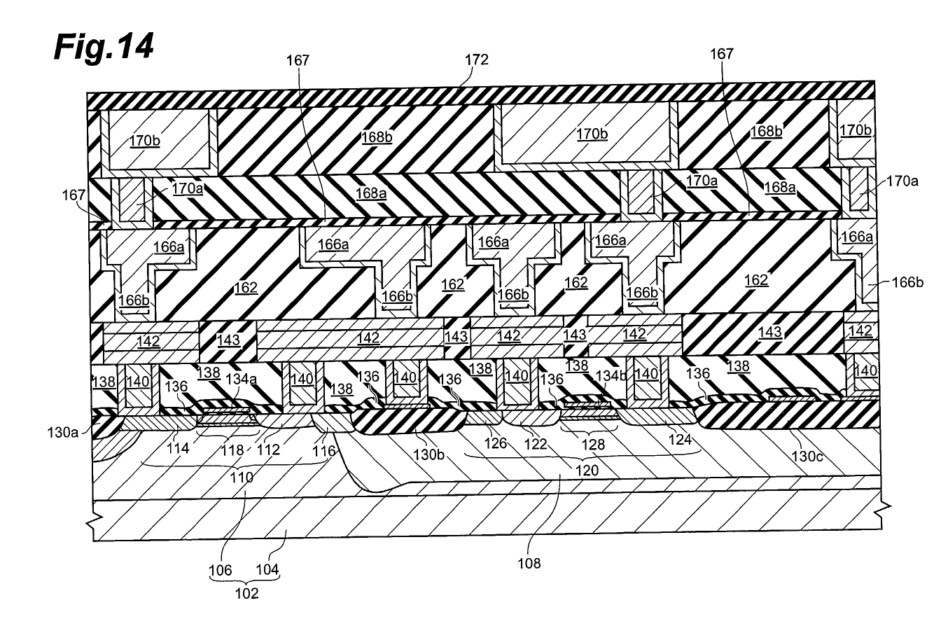

FIG. 14 shows planarized fifth silicon oxide film 168 and second conductive member 170. Third silicon nitride film 172 is formed on the planarized fifth silicon oxide film 168 and second conductive member 170. Third silicon nitride film 172, such as a silicon nitride film (plasma SiN film), plasma silicon oxide film (p-SiO film) and plasma silicon oxide nitride film (p-SiON film), acts as a passivation film.

Although the principles of the present invention have been described and illustrated with reference to preferred embodiments, it should be recognized by a person skilled in the art that the present invention could be modified in its arrangement and details without departing from these principles. For example, in the above description, although film is deposited using SiH₄ gas, SiF₄ gas and N₂O gas, process gas for the deposition is not restricted to this process gas and an inorganic silane based compound, such as disilane, can be employed instead of SiH₄, and an inorganic compound containing Si and F bonds, such as CF₄ and C₂F₆, can be used instead of SiF4. Nitrogen oxides, such as N₂O, NO, N₂O₃, N₂O₅, NO₃, N₂O₄ and NO₂ can be used as the oxygen supply source substance, and the oxygen compounds, such as CO and CO₂ and H₂O can be employed as an oxygen supply source substance. Further, 02 or 03 can be also employed. The Damascene structure means single Damascene structure or dual Damascene structure. The present invention can be applied to the manufacturing of semiconductor integrated circuit devices that do not require the filling of the gaps between the wiring conductors with insulating film.

What is claimed is:

1. A deposition method of forming a silicon inorganic insulating film on a substrate, comprising the steps of:
placing a substrate in a semiconductor manufacturing apparatus having parallel plate type electrodes; and
depositing fluorine-containing silicon insulating film on the substrate by generating plasma of process gas containing SiH₄, SiF₄ and an oxygen source substance.

2. The deposition method according to claim 1 further comprising the step of:
introducing the process gas containing SiH₄, SiF₄ and oxygen source substance into a chamber.

3. The deposition method according to claim 1 wherein the RF power applied to said parallel plate type electrodes is 1000 Watts or more.

4. The deposition method according to claim 1 wherein the RF power applied to said parallel plate type electrodes is 1400 Watts or more.

5. The deposition method according to claim 1, wherein said oxygen source substance includes at least one substance of N₂O, NO, N₂O₃, N₂O₅, NO₃, N₂O₄ and NO₂.

6. The deposition method according to claim 1, wherein said oxygen source substance includes at least one substance of 02 and 03.

7. The deposition method according to claim 1, wherein said oxygen source substance includes at least one substance of CO, CO₂ and H₂O.

8. The deposition method according to claim 1, wherein the RF power applied to said parallel plate type electrodes is at least 4 Watts/sccm.

9. The deposition method according to claim 1, wherein the flow rate ratio of said SiF₄ to said SiH₄ is larger than 1.

10. The deposition method according to claim 1, wherein the RF power applied to said parallel plate type electrodes is modulated with a single frequency.

11. The deposition method according to claim 1, wherein the pressure in said reaction chamber in said deposition step is not more than 666 Pa.

12. The deposition method according to claim 1, wherein the deposition temperature in said deposition step is not more than 480 C.

13. A method of manufacturing a semiconductor device having conductive portions of Damascene structure on a substrate, comprising the steps of:
depositing fluorine-containing silicon insulating film on a substrate by generating the plasma of process gas containing SiH4, SiF4 and an oxygen source substance, said process gas being introduced into the chamber of the semiconductor manufacturing apparatus having parallel plate type electrodes; and
forming said conductive portions of Damascene structure in said silicon insulating film.

14. The method according to claim 13 wherein said Damascene step comprises the steps of:
forming depressed portions in said silicon insulating film; and
forming conductive material in said depressed portions.

15. The method according to claim 13, wherein the RF power applied to said parallel plate type electrodes is at least 1000 Watts.

16. The method according to claim 13, wherein the RF power applied to said parallel plate type electrodes is 1400 Watts or more.

17. The method according to claim 13, wherein the RF power applied to said parallel plate type electrodes is at least 4 Watts/sccm.

18. The method according to claim 13, wherein the flow rate ratio of said SiF₄ to said SiH₄ is larger than 1.

19. A deposition apparatus comprising:
parallel plate type electrodes arranged in a chamber; means for introducing process gas containing SiH₄,
SiF₄ and oxygen source substance into said chamber; and a power source for supplying RF power for generating a plasma of said process gas, said power source being capable of supplying RF power of at least 1000 Watts to said parallel plate type electrodes.

20. The deposition apparatus according to claim 19 wherein the separation of said parallel plate type electrodes is at least 0.5 cm and not more than 1.75 cm.
